(19) United States
(12) Patent Application Publication
(10) Pub. No.: US 2024/0417620 A1
(43) Pub. Date: Dec. 19, 2024

(54) MOLYBDENUM FILM ETCHANT COMPOSITION AND ETCHING METHOD USING SAME

(71) Applicant: YCCHEM CO., LTD., Seongju-gun (KR)

(72) Inventors: Jun Han KIM, Daegu (KR); Seung Oh JIN, Daegu (KR); Seung Hyun LEE, Daegu (KR); Seung Hun LEE, Daegu (KR)

(21) Appl. No.: 18/814,585

(22) Filed: Aug. 26, 2024

Related U.S. Application Data
(63) Continuation of application No. PCT/KR2022/016316, filed on Oct. 25, 2022.

(30) Foreign Application Priority Data
Mar. 22, 2022 (KR) 10-2022-0035197

(51) Int. Cl. C09K 13/08; H01L 21/3213

(52) U.S. Cl. CPC C09K 13/08; H01L 21/32134

(57) ABSTRACT

The present invention relates to an etchant composition for etching a molybdenum film and a modified molybdenum film while suppressing the etching of an aluminum oxide film and a silicon oxide film, and an etching method therefor, wherein the etchant composition comprises, with respect to the total weight of the composition: 0.1 to 10% by weight of inorganic acid; 0.001 to 5% by weight of an oxidizer; 0.001 to 3% by weight of a fluorine compound; 2 to 4% by weight of a pH adjusting agent; 0.0001 to 2% by weight of an additive; and a residual amount of water.

### TECHNICAL FIELD

The present disclosure relates to an etchant composition that allows for the etching of a molybdenum film in the process of manufacturing semiconductor devices and to an etching method using the same composition. The present disclosure specifically relates to an etchant composition that allows for the sufficient etching of a molybdenum film and to an etching method using the same composition by simultaneously removing the molybdenum film and a modified molybdenum film while significantly suppressing the etching of an insulating film.

### BACKGROUND ART

Generally, in semiconductor manufacturing processes, a molybdenum film (Mo) has been used to form gate electrodes, wirings, barrier layers, or to fill contact holes or via holes, which are of thin film transistors of semiconductor devices and liquid crystal displays.

In the semiconductor manufacturing process, the molybdenum film (Mo) has been used as a conductive metal. The molybdenum film (Mo) may be used solely or in combination with an aluminum oxide film (AlOₓ) and silicon oxide film (SiOₓ) as a stacked structure.

In the semiconductor manufacturing processes, the process of removing the molybdenum film (Mo) is a dry etching process or a wet etching process, and in some cases, the dry and wet etching processes are used together.

Herein, in specific areas, it is difficult to etch the molybdenum film (Mo) while suppressing the aluminum oxide film (AlOₓ) and the silicon oxide film (SiOₓ) from being etched through a dry etching process, so a wet etching process is necessary for the etching in the specific areas.

In addition, there is a need for an etchant composition that can remove the molybdenum film (Mo) and a modified molybdenum film such as a molybdenum oxide film (MoOₓ) generated during the etching process at the same time.

Korean Patent Application Publication No. 10-2021-0051085 discloses a technique titled “Etchant Composition for Etching Molybdenum (Mo) and Pattern Formation Method Using the Same”.

The patent document discloses a method of preventing damage to the aluminum oxide (AlOₓ) and silicon oxide (SiOₓ) films by using a fluorine compound in the process of etching the molybdenum film (Mo), which are an etching target film. However, there is no specific disclosure regarding the simultaneous removal of a molybdenum film and a modified molybdenum film such as a molybdenum oxide film (MoOₓ).

That is, the conventional art discloses only the method of etching a molybdenum film (Mo) while suppressing aluminum oxide (AlOₓ) and silicon oxide (SiOₓ) films from being etched, and by the disclosed method, it is impossible to remove a molybdenum film and a modified molybdenum film such as a molybdenum oxide film (MoOₓ) generated at the same time in the process of etching the molybdenum film (Mo). Ultimately, there has been a problem in that there is no etchant composition that allows for satisfactory etching of a molybdenum film (Mo).

### DISCLOSURE

### Technical Problem

The present disclosure relates to how to etch a molybdenum film (Mo) while suppressing the etching of an aluminum oxide film (AlOₓ) and silicon oxide film (SiOₓ) in performing various wet etching processes with the molybdenum film (Mo) as well as how to solve the problem of an etchant composition of the conventional art, in which particles are generated while not simultaneously removing a modified molybdenum film, such as a molybdenum oxide film (MoOₓ). The present disclosure is to provide an etchant composition that allows for satisfactory etching of the molybdenum (Mo) by significantly suppressing the etching of the aluminum oxide film (AlOₓ) and silicon oxide film (SiOₓ) while simultaneously removing the modified molybdenum film such as the molybdenum film (Mo) and molybdenum oxide film (MoOₓ). In addition, the etchant composition is widely applicable to the semiconductor manufacturing process and problem-solving about particle generation.

The present disclosure is also to provide an etching method using the same etchant composition.

### Technical Solution

An etchant composition according to the present disclosure is one that contains an inorganic acid, an oxidizing agent, a fluorine compound, a pH adjuster, an additive represented by Formula 1 below, and a remaining amount of water. The etchant composition significantly suppresses the etching of an aluminum oxide film (AlOₓ) and silicon oxide film (SiOₓ) while simultaneously removing a molybdenum film (Mo) and modified film (molybdenum oxide film (MoOₓ)), thereby the etchant composition allows for ultimately satisfactory etching of the molybdenum film (Mo).

The inorganic acid included in the etchant composition of the present disclosure may be any one selected from the group consisting of sulfuric acid, phosphoric acid, polyphosphoric acid, hydrochloric acid, p-toluenesulfonic acid, and mixtures thereof.

Herein, the inorganic acid may have a content at an amount of 0.1% to 10% by weight based on the total weight of the etchant composition.

The oxidizing agent included in the etchant composition of the present disclosure may be any one selected from the group consisting of hydrogen peroxide, nitric acid, ammonium nitrate, ammonium phosphate, ammonium persulfate, periodic acid, urea-hydrogen peroxide, tert-butylhydroperoxide, and 2-butane peroxide.

Herein, the oxidizing agent may have a content at an amount of 0.001% to 5% by weight based on the total weight of the etchant composition.

The fluorine compound included in the etchant composition of the present disclosure may be any one selected from the group consisting of hydrofluoric acid, ammonium fluoride, tetrafluoroboric acid, and hexafluorosilicate.

Herein, the fluorine compound may have a content at an amount of 0.001% to 3% by weight based on the total weight of the etchant composition.

The pH adjuster included in the etchant composition of the present disclosure may be any one selected from the group consisting of phosphate and sulfate.

Herein, the pH adjuster may have a content at an amount of 0.1% to 10% by weight based on the total weight of the etchant composition.

The additive included in the etchant composition of the present disclosure are represented by Formula 1. The additive represented by Formula 1 may have a content at an amount of 0.0001% to 2% by weight based on the total weight of the etchant composition.

F(CF2CF2)×CH2CH2OH [Formula 1]

(In Formula 1, x is an integer in a range of 1 to 10.)

The etchant composition allows for maintaining a remarkably fast etching rate of the molybdenum film (Mo) and modified film (molybdenum oxide film (MoOₓ)) required in the process, while also controlling the components and composition ratio of the composition to suppress the etching of the aluminum oxide film (AlOₓ) and silicon oxide film (SiOₓ). The etchant composition particularly allows for adjusting the content of the additive represented by Formula 1. Accordingly, it is possible to suppress the etching of the aluminum oxide film (AlOₓ) and silicon oxide film (SiOₓ) while etching the molybdenum film (Mo) and modified film (molybdenum oxide film (MoOₓ)).

A temperature in an etching process with the etchant composition may be in a range of room temperature to 60° C. To increase the stability of the etching process, the inorganic acid and the remaining components may be mixed and used within a facility. When the inorganic acid and the remaining components are mixed outside the facility, the inorganic acid and the remaining components may be mixed and used immediately before the etching process.

### Advantageous Effects

The etchant composition of the present disclosure is effective in etching a molybdenum film (Mo) while suppressing the etching of an aluminum oxide film (AlOₓ) and silicon oxide film (SiOₓ) in performing various wet etching processes with the molybdenum film (Mo) as well as solving the problem of the etchant composition of the conventional art, in which particles are generated while not simultaneously removing a modified molybdenum film, such as a molybdenum oxide film (MoOₓ). The present disclosure is effective in providing an etchant composition that allows for satisfactory etching of the molybdenum film (Mo) by significantly suppressing the etching of the aluminum oxide film (AlOₓ) and silicon oxide film (SiOₓ) while simultaneously removing the modified molybdenum film such as the molybdenum films (Mo) and molybdenum oxide film (MoOₓ). In addition, the etchant composition is widely applicable to the semiconductor manufacturing process and particle generation problem-solving. Additionally, the present disclosure provides an etching method using the same etchant composition.

### Best Mode

Hereinafter, the present disclosure will be described in more detail. Unless otherwise defined, all technical and scientific terms used in the specification of the present disclosure have the same meaning as commonly understood by a skilled expert in the technical field to which the present disclosure pertains.

In general, the nomenclature used in the specification of the present disclosure is well-known and commonly used in the technical field to which the present disclosure pertains. Throughout the specification of the present disclosure, when it is said that a part “includes” a certain component, this means that it may further include other components rather than excluding other components unless specifically stated to the contrary.

An etchant composition according to one embodiment of the present disclosure is one that contains an inorganic acid, an oxidizing agent, a fluorine compound, a pH adjuster, an additive, and a remaining amount of water. The etchant composition significantly suppresses the etching of an aluminum oxide film (AlOₓ) and silicon oxide film (SiOₓ) while simultaneously removing a molybdenum film (Mo) and modified film (molybdenum oxide film (MoOₓ)), thereby ultimately, the etchant composition allows for satisfactory etching of the molybdenum film (Mo).

The inorganic acid included in the etchant composition of the present disclosure according to another embodiment of the present disclosure may be any one selected from the group consisting of sulfuric acid, phosphoric acid, polyphosphoric acid, hydrochloric acid, p-toluenesulfonic acid, and mixtures thereof.

Herein, the inorganic acid may have a content at an amount of 0.1% to 10% by weight based on the total weight of the etchant composition.

In addition, the oxidizing agent included in the etchant composition of the present disclosure may be any one selected from the group consisting of hydrogen peroxide, nitric acid, ammonium nitrate, ammonium phosphate, ammonium persulfate, periodic acid, urea-hydrogen peroxide, tert-butylhydroperoxide, and 2-butane peroxide.

Herein, the oxidizing agent may have a content at an amount of 0.001% to 5% by weight based on the total weight of the etchant composition.

The fluorine compound included in the etchant composition of the present disclosure may be any one selected from the group consisting of hydrofluoric acid, ammonium fluoride, tetrafluoroboric acid, and hexafluorosilicate.

Herein, the fluorine compound may have a content at an amount of 0.001% to 3% by weight based on the total weight of the etchant composition.

The pH adjuster included in the etchant composition of the present disclosure may be any one selected from the group consisting of phosphate and sulfate.

Herein, the pH adjuster may have a content at an amount of 0.1% to 10% by weight based on the total weight of the etchant composition.

The additive included in the etchant composition of the present disclosure are represented by Formula 1. The additive represented by Formula 1 may have a content at an amount of 0.0001% to 2% by weight based on the total weight of the etchant composition.

F(CF2CF2)×CH2CH2OH [Formula 1]

(In Formula 1, x is an integer in a range of 1 to 10.)

In yet another embodiment, the present disclosure relates to an etchant composition and etching method using the same etching composition, the etching composition containing 0.1% to 10% by weight of inorganic acid; 0.001% to 5% by weight of oxidizing agent; 0.001% to 3% by weight of fluorine compound; 2% to 4% by weight of pH adjuster; 0.0001% to 2% by weight of additive; and the remaining amount of water based on the total weight of the composition and being for etching the molybdenum film and modified molybdenum film while suppressing etching of the aluminum oxide film and silicon oxide film.

The etchant composition allows for maintaining a remarkably fast etching rate of the molybdenum film (Mo) and modified film (molybdenum oxide film (MoOₓ)) required in the process, while also controlling the components and composition ratio of the composition to suppress the etching of the aluminum oxide film (AlOₓ) and silicon oxide film (SiOₓ). The etchant composition particularly allows for adjusting the content of the additive represented by Formula 1. Accordingly, it is possible to suppress the etching of the aluminum oxide film (AlOₓ) and silicon oxide film (SiOₓ) while etching the molybdenum film (Mo) and modified film (molybdenum oxide film (MoOₓ)).

A temperature in an etching process with the etchant composition may be in a range of room temperature to 60° C. To increase the stability of the etching process, the inorganic acid and the remaining components may be mixed and used within the facility. When the inorganic acid and the remaining components are mixed outside the facility, the inorganic acid and the remaining components may be mixed and used immediately before the etching process.

### MODE FOR DISCLOSURE

### Examples 1 to 22 and Comparative Examples 1 to 9

The etchant compositions of Examples and Comparative Examples were placed in each experimental beaker equipped with a magnetic bar at the corresponding composition ratio shown in [Table 1]. Afterward, the top of each beaker was sealed and stirred at a speed of 400 rpm for 30 minutes at room temperature to prepare compositions.

TABLE 1

| | Inorganic acid | | Oxidizing agent | | Fluorine compounds | | pH adjuster | | Additive | | | |
|---|---|---|---|---|---|---|---|---|---|---|---|---|
| | | Content | | Content | | Content | | Content | | Content | Water | |
| | Compo- | (weight | Compo- | (weight | Compo- | (weight | Compo- | (weight | Compo- | (weight | Compo- | |
| Division | nent | %) | nent | %) | nent | %) | nent | %) | nent | %) | nent | Content |
| Example | A-1 | 2 | B-1 | 0.05 | C-1 | 0.08 | D-1 | 3 | E-1 | 0.05 | F-1 | Remaining |
| 1 | | | | | | | | | | | | amount |
| Example | A-1 | 3 | B-1 | 0.05 | C-1 | 0.01 | D-1 | 3 | E-1 | 0.01 | F-1 | Remaining |
| 2 | | | | | | | | | | | | amount |
| Example | A-1 | 3 | B-1 | 0.05 | C-1 | 0.001 | D-1 | 3 | E-1 | 0.05 | F-1 | Remaining |
| 3 | | | | | | | | | | | | amount |
| Example | A-1 | 3 | B-1 | 0.05 | C-1 | 0.005 | D-1 | 3 | E-1 | 0.05 | F-1 | Remaining |
| 4 | | | | | | | | | | | | amount |
| Example | A-1 | 2 | B-1 | 0.05 | C-1 | 0.1 | D-1 | 3 | E-1 | 0.05 | F-1 | Remaining |
| 5 | | | | | | | | | | | | amount |
| Example | A-1 | 2 | B-1 | 0.05 | C-1 | 0.7 | D-1 | 3 | E-1 | 0.05 | F-1 | Remaining |
| 6 | | | | | | | | | | | | amount |
| Example | A-1 | 2 | B-1 | 0.05 | C-1 | 0.7 | D-1 | 3 | E-2 | 0.05 | F-1 | Remaining |
| 7 | | | | | | | | | | | | amount |
| Example | A-1 | 2 | B-1 | 0.05 | C-1 | 0.7 | D-1 | 3 | E- 3 | 0.05 | F-1 | Remaining |
| 8 | | | | | | | | | | | | amount |
| Example | A-1 | 2 | B-1 | 0.05 | C-1 | 0.7 | D-1 | 3 | E-4 | 0.05 | F-1 | Remaining |
| 9 | | | | | | | | | | | | amount |
| Example | A-1 | 2 | B-1 | 0.05 | C-1 | 0.7 | D-1 | 3 | E-5 | 0.05 | F-1 | Remaining |
| 10 | | | | | | | | | | | | amount |
| Example | A-1 | 10 | B-1 | 0.05 | C-1 | 0.7 | D-1 | 3 | E-1 | 0.05 | F-1 | Remaining |
| 11 | | | | | | | | | | | | amount |
| Example | A-1 | 0.1 | B-1 | 0.05 | C-1 | 0.7 | D-1 | 3 | E-1 | 0.05 | F-1 | Remaining |
| 12 | | | | | | | | | | | | amount |
| Example | A-1 | 2 | B-1 | 0.001 | C-1 | 0.7 | D-1 | 3 | E-1 | 0.05 | F-1 | Remaining |
| 13 | | | | | | | | | | | | amount |
| Example | A-1 | 2 | B-1 | 5 | C-1 | 0.7 | D-1 | 3 | E-1 | 0.05 | F-1 | Remaining |
| 14 | | | | | | | | | | | | amount |
| Example | A-1 | 2 | B-1 | 0.05 | C-1 | 0.001 | D-1 | 3 | E-1 | 0.05 | F-1 | Remaining |
| 15 | | | | | | | | | | | | amount |
| Example | A-1 | 2 | B-1 | 0.05 | C-1 | 3 | D-1 | 3 | E-1 | 0.05 | F-1 | Remaining |
| 16 | | | | | | | | | | | | amount |
| Example | A-1 | 2 | B-1 | 0.05 | C-1 | 0.7 | D-1 | 3 | E-1 | 0.0001 | F-1 | Remaining |
| 17 | | | | | | | | | | | | amount |
| Example | A-1 | 2 | B-1 | 0.05 | C-1 | 0.7 | D-1 | 3 | E-1 | 2 | F-1 | Remaining |
| 18 | | | | | | | | | | | | amount |
| Example | A-2 | 2 | B-1 | 0.05 | C-1 | 0.7 | D-1 | 3 | E-1 | 0.05 | F-1 | Remaining |
| 19 | | | | | | | | | | | | amount |
| Example | A-2 | 2 | B-2 | 0.05 | C-1 | 0.7 | D-1 | 3 | E-1 | 0.05 | F-1 | Remaining |
| 20 | | | | | | | | | | | | amount |
| Example | A-2 | 2 | B-1 | 0.05 | C-2 | 0.7 | D-1 | 3 | E-1 | 0.05 | F-1 | Remaining |
| 21 | | | | | | | | | | | | amount |
| Example | A-2 | 2 | B-1 | 0.05 | C-3 | 0.7 | D-1 | 3 | E-1 | 0.05 | F-1 | Remaining |
| 22 | | | | | | | | | | | | amount |
| Compar- | A- | 0.05 | B-1 | 0.05 | C-1 | 0.7 | D-1 | 3 | E-1 | 0.05 | F-1 | Remaining |
| ative | | | | | | | | | | | | amount |
| Example | | | | | | | | | | | | |
| 1 | | | | | | | | | | | | |
| Compar- | A-2 | 0.08 | B-1 | 0.05 | C-1 | 0.7 | D-1 | 3 | E-1 | 0.05 | F-1 | Remaining |
| ative | | | | | | | | | | | | amount |
| Example | | | | | | | | | | | | |
| 2 | | | | | | | | | | | | |
| Compar- | A-1 | 2 | B-1 | 0.0005 | C-1 | 0.7 | D-1 | 3 | E-1 | 0.05 | F-1 | Remaining |
| ative | | | | | | | | | | | | amount |
| Example | | | | | | | | | | | | |
| 3 | | | | | | | | | | | | |
| Compar- | A-1 | 2 | B-1 | 6 | C-1 | 0.7 | D-1 | 3 | E-1 | 0.05 | F-1 | Remaining |
| ative | | | | | | | | | | | | amount |
| Example | | | | | | | | | | | | |
| 4 | | | | | | | | | | | | |
| Compar- | A-1 | 2 | B-1 | 0.05 | C-1 | 0.0005 | D-1 | 3 | E-1 | 0.05 | F-1 | Remaining |
| ative | | | | | | | | | | | | amount |
| Example | | | | | | | | | | | | |
| 5 | | | | | | | | | | | | |
| Compar- | A-1 | 2 | B-1 | 0.05 | C-1 | 5 | D-1 | 3 | E-1 | 0.05 | F-1 | Remaining |
| ative | | | | | | | | | | | | amount |
| Example | | | | | | | | | | | | |
| 6 | | | | | | | | | | | | |
| Compar- | A-1 | 2 | B-1 | 0.05 | C-1 | 0.7 | D-1 | 3 | E-1 | 0.00005 | F-1 | Remaining |
| ative | | | | | | | | | | | | amount |
| Example | | | | | | | | | | | | |
| 7 | | | | | | | | | | | | |
| Compar- | A-1 | 2 | B-1 | 0.05 | C-1 | 0.7 | D-1 | 3 | E-1 | 3 | F-1 | Remaining |
| ative | | | | | | | | | | | | amount |
| Example | | | | | | | | | | | | |
| 8 | | | | | | | | | | | | |
| Compar- | A-1 | 2 | B-1 | 0.05 | C-1 | 0.7 | D-1 | 3 | E-1 | 1 | F-1 | Remaining |
| ative | | | | | | | | | | | | amount |
| Example | | | | | | | | | | | | |
| 9 | | | | | | | | | | | | |

A-1: Phosphoric acid
A-2: Sulfuric acid
B-1: Hydrogen peroxide
B-2: Periodic acid
C-1: Hexafluorosilicate
C-2: Ammonium fluoride
C-3: Tetrabutyl ammonium fluoro
D-1: Phosphate
E-1: x=3 in Formula 1
E-2: x=4 in Formula 1
E-3: x=5 in Formula 1
E-4: x=6 in Formula 1
E-5: x=7 in Formula 1
F-1: Deionized water

### Experimental Examples 1 to 22 and Comparative Experimental Examples 1 to 9

The etching rates of a molybdenum film (Mo), modified film (molybdenum oxide film (MoOₓ)), aluminum oxide film (AlOₓ), and silicon oxide film (SiOₓ) due to the etchant compositions prepared in Examples 1 to 22 and Comparative Examples 1 to 9 were measured. The results are shown in Table 2 as Experimental Examples 1 to 22 and Comparative Experimental Examples 1 to 9.

First, for measurement, the wafers of the molybdenum film (Mo), aluminum oxide film (AlOₓ), and silicon oxide film (SiOₓ) were prepared by depositing them using the CVD method in the same manner as the semiconductor manufacturing process.

In addition, a MoOₓ/Mo wafer was prepared by forming a modified film (molybdenum oxide film (MoOₓ)) on the Mo surface through heat treatment onto the molybdenum film (Mo) surface at a temperature of 500° C. for 30 minutes.

Before starting etching, thickness before etching was measured using a scanning electron microscope. Afterward, the etchant compositions in a liquid state were maintained at a temperature of 60° C. in a quartz stirring tank, being stirred at a speed of 300 rpm, while the molybdenum film (Mo), modified film (molybdenum oxide film (MoOₓ)), aluminum oxide film (AlOₓ), and silicon oxide film (SiOₓ) wafers were immersed in the etchant compositions. By doing so, an etching process was performed for 1 minute.

After the etching was completed, the wafers were washed with ultrapure water, and the remaining etching solution and moisture were completely dried using a drying device.

The thin film thickness of the dried wafer coupons was measured after etching using a scanning electron microscope. Hereby, the one-minute etching amount of the molybdenum film (Mo), modified film (molybdenum oxide film (MoOₓ)), aluminum oxide film (AlOₓ), and silicon oxide film (SiOₓ) were measured at a predetermined temperature by calculating the differences in thin film thickness before and after etching.
<Evaluation criteria>
Molybdenum film (Mo)
⊚: Etching rate of 10 Å/min or more
○: Etching rate of 3 Å/min to less than 10 Å/min
Δ: Etching rate of 1 Å/min to less than 3 Å/min
x: Etching rate of 0 Å/min or less
Molybdenum oxide film (MoOₓ)
⊚: Etching rate of 10 Å/min or more
○: Etching rate of 1 Å/min to less than 10 Å/min
*Δ: Etching rate of less than 1 Å/min
x: Etching rate of 0 Å/min or less
Aluminum oxide film (AlOₓ)
⊚: Etching rate of less than 1 Å/min
○: Etching rate of 1 Å/min to less than 2 Å/min
Δ: Etching rate of 2 Å/min to less than 3 Å/min
x: Etching rate of 3 Å/min or more
Silicon oxide film (SiOₓ)
⊚: Etching rate of less than 1 Å/min
○: Etching rate of 1 Å/min to less than 2 Å/min
Δ: Etching rate of 2 Å/min to less than 3 Å/min
x: Etching rate of 3 Å/min or more

TABLE 2

Etching amount (Å)

| Division | Mo | MoOₓ | AlOₓ | SiOₓ |
|---|---|---|---|---|
| Experimental Example 1 | ◯ | ◯ | ◯ | ◯ |
| Experimental Example 2 | ◯ | ◯ | ◯ | ◯ |
| Experimental Example 3 | ◯ | ◯ | ◯ | ◯ |
| Experimental Example 4 | ◯ | ◯ | ◯ | ◯ |
| Experimental Example 5 | ◯ | ◯ | ◯ | ◯ |
| Experimental Example 6 | ◯ | ◯ | ◯ | ◯ |
| Experimental Example 7 | ⊚ | ◯ | ◯ | ◯ |
| Experimental Example 8 | ⊚ | ◯ | ◯ | ◯ |
| Experimental Example 9 | ⊚ | ⊚ | ⊚ | ◯ |
| Experimental Example 10 | ⊚ | ⊚ | ⊚ | ⊚ |
| Experimental Example 11 | ⊚ | ⊚ | ◯ | ◯ |
| Experimental Example 12 | ◯ | ◯ | ◯ | ◯ |
| Experimental Example 13 | ◯ | ◯ | ◯ | ◯ |
| Experimental Example 14 | ⊚ | ⊚ | ◯ | ◯ |
| Experimental Example 15 | ◯ | ◯ | ◯ | ◯ |
| Experimental Example 16 | ⊚ | ⊚ | ◯ | ◯ |
| Experimental Example 17 | ◯ | ◯ | ◯ | ◯ |
| Experimental Example 18 | ⊚ | ⊚ | ◯ | ◯ |
| Experimental Example 19 | ◯ | ◯ | ◯ | ◯ |
| Experimental Example 20 | ◯ | ◯ | ◯ | ◯ |
| Experimental Example 21 | ◯ | ◯ | ◯ | ◯ |
| Experimental Example 22 | ◯ | ◯ | ◯ | ◯ |
| Comparative Experimental | ◯ | ◯ | Δ | Δ |
| Example 1 | | | | |
| Comparative Experimental | ◯ | ◯ | Δ | Δ |
| Example 2 | | | | |
| Comparative Experimental | ◯ | ◯ | X | X |
| Example 3 | | | | |
| Comparative Experimental | ⊚ | ⊚ | X | X |
| Example 4 | | | | |
| Comparative Experimental | ◯ | ◯ | Δ | Δ |
| Example 5 | | | | |
| Comparative Experimental | ⊚ | ⊚ | X | X |
| Example 6 | | | | |
| Comparative Experimental | ◯ | ◯ | X | X |
| Example 7 | | | | |
| Comparative Experimental | ⊚ | ⊚ | X | X |
| Example 8 | | | | |
| Comparative Experimental | ◯ | ◯ | X | X |
| Example 9 | | | | |

As shown in [Table 2] above, looking at the results of Experimental Examples 1 to 22, satisfactory etching amounts of the molybdenum film (Mo) and the modified film (molybdenum oxide film (MoOx)) were achieved while the etching of the aluminum oxide film (AlOₓ) and silicon oxide film (SiOₓ) were significantly suppressed effectively.

In comparison, looking at the results of Comparative Experiment Examples 1 to 9, satisfactory etching amounts of the molybdenum film (Mo) and modified film (molybdenum oxide film (MoOₓ)) were achieved, but the etching of the aluminum oxide film (AlOₓ) and silicon oxide film (SiOₓ) was not significantly suppressed. Thus, the compositions of Comparative Experiment Examples 1 to 9 may not be used as the etchant of the present disclosure.

As above, specific parts of the present disclosure have been described in detail. It will be clear that for those skilled in the art, these specific techniques are merely preferred examples and do not limit the scope of the present disclosure. Accordingly, the actual scope of the present disclosure will be defined by the claims and their equivalents.

1. An etchant composition for etching a molybdenum film and a modified molybdenum film while suppressing an aluminum oxide film and a silicon oxide film from being etched, the etchant composition comprising:
an inorganic acid;
an oxidizing agent;
a fluorine compound;
a pH adjuster;
an additive; and
water.

2. The etchant composition of claim 1, comprising, based on the total weight of the composition:
0.1% to 10% by weight of the inorganic acid;
0.001% to 5% by weight of the oxidizing agent;
0.001% to 3% by weight of the fluorine compound;
2% to 4% by weight of the pH adjuster;
0.0001% to 2% by weight of additive; and
a remaining amount of the water.

3. The etchant composition of claim 1, wherein the inorganic acid is any one selected from the group consisting of a sulfuric acid, a phosphoric acid, a polyphosphoric acid, a hydrochloric acid, a p-toluenesulfonic acid, and mixtures thereof.

4. The etchant composition of claim 1, wherein the oxidizing agent is any one selected from the group consisting of a hydrogen peroxide, a nitric acid, an ammonium nitrate, an ammonium phosphate, an ammonium persulfate, a periodic acid, a urea-hydrogen peroxide, a tert-butylhydroperoxide, and a 2-butane peroxide.

5. The etchant composition of claim 1, wherein the fluorine compound is any one selected from the group consisting of a hydrofluoric acid, an ammonium fluoride, a tetrafluoroboric acid, and a hexafluorosilicate.

6. The etchant composition of claim 1, wherein the pH adjuster is any one selected from the group consisting of a phosphate and a sulfate.

7. The etchant composition of claim 1, wherein the additive is a compound represented by Formula 1 below,
F(CF2CF2)×CH2CH2OH, [Formula 1]
(wherein in Formula 1, x is a natural number in a range of 1 to 10.).

8. The etchant composition of claim 7, wherein the additive has a condition that x in Formula 1 is an integer in a range of 3 to 7.

9. A method of etching a molybdenum film and a modified molybdenum film while suppressing an aluminum oxide film and a silicon oxide film from being etched by using the etchant composition of claim 1.

10. The method of claim 9, wherein the molybdenum film is etched at an etching rate of 3 Å/min or more, a molybdenum oxide film is etched at an etching rate of 3 Å/min or more, the aluminum oxide film is etched at an etching rate of less than 2 Å/min, and the silicon oxide film is etched at an etching rate of less than 2 Å/min.
